(19) United States
(12) Patent Application Publication
(10) Pub. No.: US 2024/0209512 A1
(43) Pub. Date: Jun. 27, 2024

(54) METHOD FOR PLASMA-TREATING A SURFACE OF A SUBSTRATE

(71) Applicant: Atotech Deutschland GmbH & Co. KG, Berlin (DE)

(72) Inventors: Frank BRÜNING, Berlin (DE); Sebastian DÜNNEBEIL, Berlin (DE); Jörg SCHULZE, Berlin (DE); Edith STEINHÄUSER, Berlin (DE); Sebastian ZARWELL, Berlin (DE)

(73) Assignee: Atotech Deutschland GmbH & Co. KG, Berlin (DE)

(21) Appl. No.: 18/553,028

(22) PCT Filed: Mar. 31, 2022
(86) PCT No.: PCT/EP2022/058516

§ 371 Date: Sep. 28, 2023

(30) Foreign Application Priority Data
Mar. 31, 2021 (EP) 21166322.4

(51) Int. Cl. C23C 18/20; C23C 18/16; C23C 18/22; C23C 18/38; C23C 28/02; C25D 3/38

(52) U.S. Cl. CPC C23C 18/2026; C23C 18/1641; C23C 18/1653; C23C 18/1692; C23C 18/22; C23C 18/38; C23C 28/023; C25D 3/38

(57) ABSTRACT

The present invention relates to a method for plasma-treating a surface of a substrate, in particular a dielectric substrate, the method including the following steps:
(t) wet-chemical treating the surface of the substrate with treatment solutions of a desmear process, to obtain a wet-chemical treated surface of the substrate,
(i) treating a surface of the substrate with a plasma beam under atmospheric pressure, to obtain a plasma-treated surface of the substrate,
(ii) activation of the plasma-treated surface of the substrate with an activation composition, to obtain an activated surface of the substrate,
(iii) optionally electroless deposition of a coating metal on the activated surface of the substrate, to obtain a plating surface of the substrate, and
(iv) optionally electrolytic deposition of an additional coating metal on the plating surface of the substrate obtained after optional step (iii) or on the activated surface of the substrate obtained after step (ii).

### FIELD OF THE INVENTION

The present invention according to a first aspect relates to a method for plasma-treating a surface of a substrate, in particular a dielectric substrate.

In particular, the method comprises the following steps, (i) treating a surface of the substrate with a plasma beam under atmospheric pressure, to obtain a plasma-treated surface of the substrate, (ii) activation of the plasma-treated surface of the substrate with an activation composition, to obtain an activated surface of the substrate, and (iii) optionally electroless deposition of a coating metal on the activated surface of the substrate, to obtain a plating surface of the substrate.

According to a second aspect the present invention is further directed to a substrate with a metal coated surface obtained by a method according to the first aspect.

### BACKGROUND OF THE INVENTION

The wet-chemical deposition of metal layers onto substrate surfaces has a long tradition in the art. This wet-chemical deposition can be achieved by means of electrolytic or electroless plating of coating metals. Electroless plating is the controlled autocatalytic deposition of a continuous film of the coating metal without the assistance of an external supply of electrons. Contrary to that, electrolytic plating requires such an external supply of electrons.

These methods are of high importance in the electronics industry and, among other applications, are used in the manufacturing of printed circuit boards, semiconductor devices and similar goods. The most important coating metal in this regard is copper as it is used for the build-up of the conductive lines forming the circuitry in said goods.

Since most conventional substrates comprise non-metallic and thereby nonconductive surfaces, said substrate surfaces typically must be activated in order to make them receptive for an electroless electrolytic and/or plating process. This activation of nonconductive substrates such as glass substrates, silicon substrates and plastic substrates may employ a catalysing metal such as copper, silver, gold, palladium, platinum, rhodium, cobalt, ruthenium, iridium or electrically conductive coatings such as conductive organic polymers or carbon like carbon black, graphite, carbon tubes or graphene. Such activation, for example with a catalysing metal, normally does not result in a discrete layer but in an island-like structure of spots on the surface of the substrate. Such activation may be achieved by the adsorption of a catalysing metal onto the surface of the substrate. By such activation, it is possible to sensitize substrates prior to the deposition of the metal or metal alloy thereon.

However, before activation of the non-metallic, i.e. nonconductive substrate surfaces typically pre-treatment processes must be performed, which inter alia comprise desmear, swelling, etching, reducing, rinsing, or cleaning processes. These processes include among others removal of surface residues with organic solvents, acidic or alkaline aqueous solutions or solutions comprising surfactants, reducing agents and/or oxidation agents.

Facing a demand for increasing miniaturization, modern electronics manufacturers must pursue the trend to more and more densely interconnected multilayer printed circuit boards. Owing to their low cost and well-balanced physicochemical and mechanical properties, epoxy-based composite substrates are insulating materials of prime choice. The latest epoxy build up laminates contain increasing amounts of spherical glass filler, which are needed to compensate the CTE mismatch between the epoxy-based resin matrix and the electroplated copper circuits. In addition, their small size in the order of μm and below, allows for smoother surface topographies compared to glass fiber bundle reinforced base materials.

After inserting different recesses as traces, blind micro vias (BMVs) or through holes (THs) e.g. by drilling into the resin-based substrate comprising the glass filler, typically a desmear process is applied to remove residues of the drilling process. During industrial desmear processing the adhesion of the exposed glass filler at the surface of the substrate and at the surface of the recesses will be weakened and their anchoring in the surrounding resin matrix will be lost or damaged. If this filler will not be removed, the remaining weak-bounded or loose filler may give rise to low adhesion of plated copper on the epoxy resin, as well as contaminated copper to copper connections in blind micro vias (BMVs) or through holes (THs). This can affect yield rates in production and reliability in the final product.

Common approaches to overcome the glass filler contamination include fluoride etch solutions described in US 2012/0298409 A1 and ultrasonic treatment described in US 2007/0131243 A1. Neither of these strategies is easily applicable in the vertical mode of semi additive processing (SAP). The drastic health issues of fluoride etching solutions quickly disqualify them for most parts of the industry, whereas ultrasound application in vertical mode, possibly even in basket application, is extremely difficult to employ in a homogeneous fashion with sufficiently high impact on each panel.

JP 2010-229536 A discloses a pretreatment agent for cleaning surface of a resin substrate containing silica-based filler wherein the filler and the glass fiber shall be removed which are exposed on the substrate surface after desmear treatment etc. The pretreatment agent includes an alkali, a nonionic ether type surfactant, and an amine-based complexing agent.

WO 2019/206682 relates to metal plating of nonmetallic substrates. More particularly, it relates to a method particularly suitable for plating particularly smooth polymer-containing substrates with a metal such as copper, palladium, nickel, silver, nickel phosphorous (Ni—P), nickel boron (Ni—B), cupronickel or other metal.

KR 20080011259 discloses a plasma-pretreatment process to avoid conventional chemicals pretreatment in wet plating of metal or non-metal materials such as ABS resin or PCB.

US 2010/272902 A1 relates to a plating method comprising: (a) applying a plating catalyst liquid containing a catalytic element and an organic solvent, to an object to be plated having, at least at a surface thereof, a functional group capable of forming an interaction with the catalytic element; and (b) performing plating on the object to be plated, to which the plating catalyst liquid has been applied.

US20170306496A1 relates to a multi-layered elastomer article and to a method for its manufacturing. The multilayered article made of an elastomeric composition (C) comprising at least one elastomer, said article having at least one surface (S) comprising: -nitrogen-containing groups (N) and—at least one layer (LI) adhered to said surface (S) comprising at least one metal compound (M).

WO 2005/087979 A2 discloses a method and a device for depositing a metal layer on a non-conducting surface of a substrate. Within the method, (a) a liquid composition containing metal ions is directed to at least a part of the surface and (b) a reductive agent is directed to at least a part of the surface. The metal ions are reduced in situ into the metallic form in those parts onto which both (a) and (b) have been directed. The reduction reaction and the adherence to the non-conducting surface can be supported by treatment with physical energy such as treatment with atmospheric.

The aforementioned conventional approaches often contain hazardous to health components. Further, the conventionally used solutions do not sufficiently remove loose or weakly attached filler, lead to insufficient surface pre-treatment and also tend to undesired foaming. Thus, the subsequent substrate activation can lead to the formation of an unspecific and insufficient adhered catalyzing metal layer on the surface of the substrate, which can then lead to incomplete copper deposition in the subsequent plating processes.

### OBJECTIVES OF THE PRESENT INVENTION

It was therefore the first objective of the present invention to overcome the shortcomings of the prior art and to provide means for improved removing of surface resides, i.e. loose glass filers, from a wide variety of polymer substrates, in particular in blind micro vias (BMVs) or through holes (THs) of the substrate.

It was therefore the second objective of the present invention to omit or at least significantly reduce the necessity of pre-treatment processes, for example desmear process including swelling, etching, reducing, rinsing; or other cleaning processes, for a wide variety of polymer substrates, in particular in substrates comprising blind micro vias (BMVs) or through holes (TH), in order to simplify wastewater treatment, to safe energy and time consumption and thereby reduce manufacturing costs.

It was therefore the third objective of the present invention to provide surface treatment for a wide variety of substrates to improve the subsequent activation of said treated surface, i.e. by an improved amount of surface coverage/distribution and improved adhesion of an activation composition, in particular in blind micro vias (BMVs) or through holes (TH) of said substrate wherein roughness of the substrate surface is comparable to traditionally use of wet-chemical treatments only as desmear process, at least the surface roughness is not significantly increased.

It was therefore the fourth objective of the present invention to provide surface treatment for a wide variety of substrates, which allows for a metal coating on the respective substrate, which has an excellent adhesion strength, in particular of the electrolytical deposited copper coating and is difficult to be peeled off, in particular in blind micro vias (BMVs) or through holes (TH) of the substrate.

It was therefore the fifth objective of the present invention to provide surface treatment for a wide variety of substrates, in particular low-dk, low-df material-based substrates, which allows for a metal coating on the respective substrate, which shows significantly reduced or no skin effects, signal loss.

It was therefore the sixth objective of the present invention to provide surface treatment for a wide variety of substrates, which can be included into a conventional process sequence without major amendments to other process steps, in order to reduce manufacturing costs.

### SUMMARY OF THE INVENTION

The first to sixth objectives mentioned above are solved according to a first aspect by a method for plasma-treating a surface of a dielectric substrate comprising through holes (THs) and/or blind micro vias (BMVs), the method comprising the following steps:
(t) wet-chemical treating the surface of the substrate with treatment solutions, preferably aqueous solutions, of a desmear process to remove residues from the surface of the substrate in order to obtain a wet-chemical treated surface of the substrate,
(i) treating the wet-chemical treated surface of the substrate with a plasma beam under atmospheric pressure, to obtain a plasma-treated surface of the substrate, (ii) activation of the plasma-treated surface of the substrate with an activation composition, to obtain an activated surface of the substrate,
(iii) optionally electroless deposition of a coating metal on the activated surface of the substrate, to obtain a plating surface of the substrate, and
(iv) optionally electrolytic deposition of an additional coating metal on the plating surface of the substrate obtained after optional step (iii) or on the activated surface of the substrate obtained after step (ii).

The method, in particular the combination of the wet-chemical treating step (t) and the plasma treating step (i), allows for an efficient removal of loosely or weakly attached surface residues, i.e. filler components, from the substrate, in particular in blind micro vias (BMV) or through holes (TH) of the substrate, and forms or alters functional groups at the polymer surfaces for support of chemical adhesion and wherein the plasma-treated surface roughness is not significantly increased, but can be reduced by this subsequent treatment compared to standard procedures. The method in particular improves the adhesion between the substrate and the subsequent deposited metal layers and the metal coverage of the dielectric substrate surfaces to be treated.

By performing the activation step (ii), an activation layer is deposited onto the plasma-treated surface which provides in consequence said activated surface of the substrate.

Consequently, during the subsequent activation step (ii), which follows the plasma treating step (i), the plasma-treated surface of the substrate can be effectively activated by the activation composition, which in turn improves the efficiency of any subsequent (optional electroless) deposition of coating metal, e.g. copper, on said activated substrate surface during step (iii).

Depending on the specific activation composition used during activation step (ii) only an electrolytic metal deposition step may be performed afterwards or both wherein first an electroless followed by an electrolytic metal deposition step may be performed afterwards.

For example, when palladium metal is used as activated surface of the substrate which was obtained by applying the activation composition, firstly an electroless coating metal deposition step (iii) is performed after activation step (ii), and secondly an electrolytic metal deposition step is performed after the electroless coating metal deposition step (iii).

Alternatively, when carbon like carbon black, graphite, carbon tubes or graphene, colloidal metals or conductive polymers are used as activated surface of the substrate by applying the activation composition, for example the optional electroless metal deposition step (iii) can be omitted and only the electrolytic metal deposition step is performed after the activation step (ii).

Consequently, a well metal coated substrate can be obtained, wherein the metal coating has an excellent adhesion strength, an excellent optical appearance, and an excellent mechanical strength. Additionally, the coverage of the metal coating at the substrate is improved.

Further, due to the high efficiency of the plasma treating step (i), the desmear process including e.g. swelling, etching, reducing, rinsing and/or cleaning processes can be reduced, such that the treatment of wastewater can be simplified, the energy and time consumption can be reduced, and consequently the manufacturing costs can be reduced.

The invention shows that the combination of wet-chemical treatment using a desmear process, followed by treatment with atmospheric plasma is beneficial. Own experiments show that the combination improves the adhesion of the subsequently deposited layers in comparison with either applying a desmear process or a plasma treatment alone. In preferred embodiments the peel strength adhesion of the obtained substrate surface after performing the inventive method steps (t) to (iv) is 5 N/cm or higher, preferably 6 N/cm or higher, most preferably from 5 to 10 N/cm. The peel strength test is performed according to IPC-TM-650 electronic standard.

Preferably, the peel strength adhesion of a substrate surface after performing the inventive method steps (t) to (iv) is at least 25% improved, more preferably improved of 25% to 150%, over performing step (t) wet-chemical treating the surface of the substrate with treatment solutions of a desmear process or step (i) treating the wet-chemical treated surface of the substrate with a plasma beam under atmospheric pressure alone. More preferred the peel strength adhesion is improved of 50% to 100%. The peel strength test is performed according to IPC-TM-650 electronic standard.

By applying a desmear process, the surface roughness of the treated substrate is normally increased and cleaned, but sometimes the obtained surface roughness is too strong which cause undesired plating effects. In one embodiment of the invention, it could be surprisingly found by performing a shorten desmear process, that the combination leads still to well-cleaned surfaces with good adhesion of the subsequent layers, but in contrast the surface roughness of the combined treatments was lower in comparison to the applied standard desmear process alone. Thus, e.g. surface distribution/coverage and also adhesion of the subsequent deposited layer is improved, and skin effect is reduced.

Since the plasma treating step (i) is performed under atmospheric pressure, there is no necessity to provide a vacuum-sealed compartment for the substrate to be plasma-treated. Therefore, plasma treating step (i) can be effectively incorporated into conventional plating processes, which also allows for an effective reduction of manufacturing costs.

The first to sixth objectives mentioned above are solved according to a second aspect by a substrate with a metal coated surface obtained by a method according to the first aspect.

Said substrate comprises an excellent metal coating according to the advantages summarized before.

### BRIEF DESCRIPTION OF THE EXAMPLES

In Examples 1, 2, 3, 4, 5 and 6, the influence of variations in the various process steps in respect to the resulting adhesion strength of the coated metal during peel-off tests are shown.

Further details are given in the “Examples” section below in the text.

### DETAILED DESCRIPTION OF THE INVENTION

In the context of the present invention, the term “at least one” or “one or more” denotes (and is exchangeable with) “one, two, three or more than three”.

In the context of the present invention, the term “and/or” includes any and all combinations of one or more of the associated listed items.

In the context of the present invention, the terms “deposition”, “coating” and “plating” are used interchangeably herein. In the context of the present invention, the terms “layer”, “coating” and “deposit” are used interchangeably herein.

In the context of the present invention, the term “dielectric” means non-metallic and thereby nonconductive.

In the context of the present invention, the term “aqueous solution” means that aqueous solution comprises water of 50 weight-% (w/w %) or more.

In the context of the present invention, the term “desmear process” means a wet-chemical process which relates in particular to a process for the removal of residues as particulates generated by laser drilling or mechanical drilling into the surface of the dielectric substrate to form through holes (THs, also named through hole vias (THVs)) and/or blind micro vias (BMVs) in the substrate. The wet-chemical process comprises at least an etching agent, preferably using aqueous acidic or alkaline permanganate solution.

In the context of the present invention, the surface of the dielectric substrate to be treated is understood as external surface of the substrate comprises a hole surface, delimiting the through-holes (THs) and blind micro vias (BMVs) which were drilled into the substrate. The external surface may further comprise e.g. an upper and a lower plane surface of the substrate which is not the hole surface, wherein steps (i), (ii), optionally (iii) and optionally (iv) are performed on said surface. At least the hole surface is treated by the method of the present invention to obtain e.g. a wet-chemical treated surface according to step (t).

The present invention according to the first aspect is directed to a method for plasma-treating a surface of a dielectric substrate comprising through holes (THs) and/or blind micro vias (BMVs), the method comprising the following steps:
(t) wet-chemical treating the surface of the substrate with treatment solutions, preferably aqueous solutions, of a desmear process to remove residues from the surface of the substrate in order to obtain a wet-chemical treated surface of the substrate,
(i) treating the wet-chemical treated surface of the substrate with a plasma beam under atmospheric pressure, to obtain a plasma-treated surface of the substrate,
(ii) activation of the plasma-treated surface of the substrate with an activation composition, to obtain an activated surface of the substrate,
(iii) optionally electroless deposition of a coating metal on the activated surface of the substrate, to obtain a plating surface of the substrate, and
(iv) optionally electrolytic deposition of an additional coating metal on the plating surface of the substrate obtained after optional step (iii) or on the activated surface of the substrate obtained after step (ii) in order to obtain an electrolytic metal coated surface.

The treating with the plasma beam is applied preferably directly to the wet-chemical treated surface after step (t) without depositing a polymer layer which functions as adhesion layer between the wet-chemical treated surface and the subsequent layers. That means, no polymer layer as a curable organic polymer layer is deposited onto the wet-chemical treated surface before step (i) and is herewith excluded.

Furthermore, step ii)—the activation of the plasma-treated surface of the substrate is preferably performed directly after applying step (i). In particular, no curable polymer layer, e.g. a curable organic polymer layer, is deposited which functions as an adhesion layer for the activation layer providing the activated surface. Thus, an adhesion layer which is formed by curing an organic polymer (e.g. curing by chemical curing, UV light radiation or plasma beam) to provide a cured polymer and/or a chemical interaction with the plasma-treated surface and the activated surface, is not needed and excluded.

The method is preferred wherein no curable polymer layer, preferably no curable organic polymer layer, is deposited onto the wet-chemical treated surface and/or the plasma-treated surface.

Preferably, substrates according to the present invention comprise boards for HDI, MLB production and/or IC substrate articles with fine features, more preferably for horizontal plating applications comprising aspect ratios of through holes (THs) from 1:3 to 1:18 and/or blind micro vias (BMVs) from 1:0.5 to 1:2.3, or more preferably for vertical plating applications comprising aspect ratios of through holes (THs) from 1:3 to about 1:30 and/or blind micro vias (BMVs) from 1:1 or down to 1:1.15 to 1:2.3.

The desmear process (t) is beneficial to prepare the surfaces of the substrate for the subsequent plasma treatment during method step (i), in particular because surface residues or fillers, which are present in the through holes (THs) or blind micro vias (BMVs) can efficiently remove by the desmear process.

Beside the desired removal of surface residues, the desmear process also roughens the surface, wherein a certain surface roughness Ra is obtained. The Ra value is measured according to DIN EN ISO 4287, DIN EN ISO 4288:1998, DIN EN ISO 13565, DIN EN 10049.

A method for plasma-treating a surface of the substrate is preferred, wherein the desmear process preferably comprises applying sub-steps for swelling, etching and reducing treatment steps and optionally rinsing and/or cleaning treatment steps of the substrate surface after a drilling process to insert through holes (THs) and/or blind micro vias (BMVs). More preferably the desmear process comprises at least three sub-steps: a (t-1) swelling step, a (t-2) etching step and a (t-3) reducing step. These sub-steps may comprise applying of treatment agents as shown below.

A method for plasma-treating a surface of the substrate is preferred, wherein step (t) comprises sub-steps (t-1), (t-2) and (t-3),
wherein sub-step (t-1) comprises applying a first treatment agent, preferably a swelling agent, to the surface of the substrate, to obtain a swollen surface of the substrate,
wherein sub-step (t-2) comprises applying a second treatment agent, preferably an etching agent, to the surface of the substrate, preferably to the swollen surface of the substrate, to obtain an etched surface of the substrate, and
wherein sub-step (t-3) comprises applying a third treatment agent, preferably a reducing agent, to the surface of the substrate, preferably to the etched surface of the substrate.

The first treatment agent, second treatment agent and third treatment agent are preferably aqueous solutions.

By applying the corresponding sub-steps (t-1), (t-2) and (t-3) a particularly effective desmear process can be ensured.

Preferably, sub-step (t-1) is the first step, followed by sub-step (t-2) as the second step, which in turn is followed by sub-step (t-3) as the third step.

Preferably, the first treatment agent, more preferably swelling agent, comprises organic solvents, which are most preferably selected as glycol ether and/or lactams, and penetrates into the exposed resin surface of through holes and BMVs. Most preferably, the swelling agent is selected as the commercially available Securiganth MV Sweller.

Preferably, the first treatment agent, more preferably swelling agent is applied at a concentration from 200 ml/l to 500 ml/l based on the total volume of the first treatment agent.

Preferably, the first treatment agent, more preferably swelling agent comprises a pH from 9.5 to 12.

Preferably, sub-step (t-1) is performed from a temperature of 55° C. to 85° C., more preferably from 60° C. to 70° C.

Preferably, sub-step (t-1) is performed for a duration from 2 min to 15 min, preferably from 5 min to 10 min.

Preferably, the second treatment agent, more preferably etching agent is selected as an aqueous solution comprising acids, more preferably sulfuric acid, and/or oxidation agents, more preferably hydrogen peroxide, or is selected as an alkaline solution, more preferably a potassium hydroxide solution, and/or oxidation agents, more preferably potassium permanganate. Most preferably, the etching agent is selected as the commercially available Securiganth P500.

Preferably, the second treatment agent, more preferably etching agent, even more preferably permanganate is applied at a concentration from 35 g/l to 70 g/l based on the total volume of the second treatment agent.

Preferably, the second treatment agent, more preferably etching agent comprises sodium hydroxide from 35 g/l to 60 g/l based on the total volume of the second treatment agent.

Preferably, sub-step (t-2) is performed from a temperature of 60° C. to 90° C., more preferably from 70° C. to 85° C., and most preferably at 80° C.

Preferably, sub-step (t-2) is performed for a duration from 1 min to 20 min, preferably from 2 min to 20 min, more preferably 2 min to 10 min.

It was surprisingly found that through the inventive combination of wet-chemical treatment and plasma treatment, the wet-chemical treatment can be shortened, if less roughen surfaces are more beneficial. Own experiments have shown although the obtained surface roughness Ra of the plasma-treated surface was reduced by 30 to 50% by using a shorten sub-step (t-2) of 2 min to 10 min (measured after plasma treatment in step (i)) in contrast to 20 min (measured after plasma treatment in step (i)), the adhesion of the subsequent metal layers was in the same desired range.

Preferably, the third treatment agent, more preferably reducing agent comprises an acid, most preferably sulfuric acid or hydrochloric acid, a reducing agent capable to reduce metal leftovers from the previous step as citric acid, ascorbic acid hypophosphates, most preferably hydroxylammonium sulfate or hydrogen peroxide, and a polymer containing nitrogen atoms and/or positively charged nitrogen atoms. Most preferably, the reducing agent is selected as the commercially available MV Reduction Conditioner or Reduction Solution.

Preferably, the third treatment agent, more preferably reducing agent, is applied at a concentration from 70 ml/l to 150 ml/l based on the total volume of the second treatment agent.

Preferably, the third treatment agent, more preferably reducing agent comprises from 80 ml/l to 120 ml/l of 50 w/w % sulfuric acid based on the total volume of the second treatment agent.

Preferably, sub-step (t-3) is performed from a temperature from 40° C. to 55° C., more preferably from 40° C. to 50° C., and most preferably at 50° C.

Preferably, sub-step (t-3) is performed for a duration from 0.5 min to 5 min, preferably for 4 min.

In particular, by applying the plasma-treatment according to the present disclosure, the adhesive strength of the metal coating can be significantly increased, which results in a mechanically stable coating layer of the substrate, wherein said coating has reduced likelihood to be peeled off the substrate.

While a certain surfaces roughness is desired to improve adhesion of subsequent deposition of metal layers, a too strong generated surface roughness has a negative effect of the surface quality of the subsequent deposited metal layers in view of the thickness uniformity of the layer and the uniformity of even surface of the layer. This might lead to problems with resistance and coverage of the deposited metal layers and an undesired skin effect starts to rise.

The substrate according to the invention comprising through-holes (THs) and/or blind micro vias (BMVs) are treated by the plasma beam under atmospheric pressure during method step (i), to obtain plasma-treated surfaces of the substrate.

Preferably, substrates according to the present invention comprise boards for HDI, MLB production and/or IC substrate articles with fine features, more preferably for horizontal plating applications comprising aspect ratios of through holes (THs) of about 1:3 to about 1:18 and/or blind micro vias (BMVs) of about 1:0.5 to 1:2.3, or more preferably for vertical plating applications comprising aspect ratios of through holes (THs) of about 1:3 to about 1:30 and/or blind micro vias (BMVs) of about 1:1 or down to 1:1.15 to 1:2.3.

The plasma beam generated during method step (i) is useful in treating the surfaces comprising a hole surface delimiting the through-holes (THs) and/or blind micro vias (BMVs) and also a plane upper and lower surface, so that these surfaces can be advantageously activated afterwards by the activation composition, thereby preventing mechanical defects in the coating at the through-holes (THs) or blind micro vias (BMVs) of the substrate.

The plasma beam according to the present disclosure is a plasma beam generated under atmospheric pressure, which is about 1 bar, which means that the substrate to be plasma-treated does not have to sealed off in a vacuum chamber. Therefore, the plasma treatment step (i) can be effectively incorporated into existing plating methods without the necessity to significantly redesign such process.

The plasma treating step (i) allows in particular to provide functional groups at the plasma-treated surface of the substrate (by forming or altering the substrate material at the surface) to support the adhesion and wettability of the activation layer which provides the activated surface of the substrate. That means, the plasma treating step (i) leads to oxidation or reduction products onto the plasma-treated surface. In consequence, the plasma-treated surface has functional groups selected from the group consisting of carbonyl, hydroxy, nitride, nitrate, amine, amide, alkenyl and alkynyl. Such functional groups formed during step (i) are preferred carbonyl, hydroxy, amine, alkenyl and alkynyl for e.g. epoxy based ABF polymer after treatment with atmospheric air plasma.

A method for plasma-treating a surface of the substrate is preferred, wherein the method comprises the following step (p), which is performed before or after step (i), or wherein step (i) is performed during step (p),
(p) pre-treating a surface of the substrate with a pre-treatment process, preferably a cleaning process, to obtain a pre-treated surface of the substrate.

The pre-treatment process, preferably cleaning process, can improve the subsequent activation of the surface of the substrate during activation step (ii). During step (p), preferably if performed before step (i) no curable polymer layer, preferably no curable organic polymer layer, will be deposited.

Preferably, step (p) is performed after plasma treating step (i) of the method. Thereby, the plasma-activated surface of the substrate obtained after step (i) is subjected to the pre-treatment step (p), which in turn is followed by the activation step (ii).

A method for plasma-treating a surface of the substrate is preferred, wherein step (p) comprises sub-steps (p-1), and/or (p-2),
wherein sub-step (p-1) comprises applying a first pre-treatment agent, preferably a cleaning agent with or without conditioning agent, to the surface of the substrate, to obtain a cleaned and conditioned surface of the substrate, and/or
wherein sub-step (p-2) comprises applying a second pre-treatment agent, preferably an etching/cleaning agent, to the surface of the substrate, preferably to the cleaned and conditioned surface of the substrate.

The first pre-treatment agent and second pre-treatment agent are aqueous solutions.

The conditioning agent is preferably not a curable polymer and does not function as adhesion promoter.

If step (p) is performed before step (i) the pre-treatment agent comprises further an agent capable of reducing manganese dioxide such as hydroxylammonium sulfate or hydrogen peroxide and if a conditioning agent is used, the conditioning agent is adsorbed at the surface of the wet-chemical treated surface, preferable to improve the wettability of the surface. In this case the conditioning agent is in particular not a curable polymer and will not be cured by the plasma treatment. E.g. Securiganth® MV Reduction Conditioner available from Atotech Deutschland Gmbh & Co. KG can be used as pre-treatment agent.

By applying the corresponding sub-steps (p-1) and/or (p-2) a particularly effective pre-treatment process (p) can be ensured.

Preferably, the pre-treatment process (p) comprises sub-step (p-1) as a first sub-step, which is followed by the second sub-step (p-2).

As a preferred alternative, the pre-treatment process (p) comprises only sub-step (p-1).

As a preferred alternative, the pre-treatment process (p) comprises only sub-step (p-2).

Preferably, the first pre-treatment agent, more preferably cleaning agent will contain additives able to produce a clean substrate and/or metal surface by removing dirt or organic left overs by using at least one anorganic base, and/or organic base such as amines as ammonia or aliphatic amines and similars or an anorganic acid such as sulfuric acid, hydrochloric acid or organic acids such as sulfonic acids, carbonic acids, acetic acid, glycolic acid preferable together with additives as conditioning agent which is able to reduce the surface tension of water as surfactants and more preferable with polymers able to adsorb on the before treated surfaces such as polymers with nitrogen atoms and/or quaternized nitrogen atoms to form a conditioned surface. Most preferably, the cleaning agent is selected as the commercially available Securiganth Cleaner V8, Cleaner 902 or Cleaner GFR.

The conditioning agent is preferably selected from the group consisting of a polymer containing quaternized nitrogen atoms, a polymer containing nitrogen atoms and mixture thereof.

Preferably, the first pre-treatment agent, more preferably cleaning agent with or without conditioning agent, is applied at a concentration from 25 ml/l to 110 ml/l based on the total volume of the first pre-treatment agent. The conditioning agent is used from 0 g/l to 20 g/l based on the total volume of the first pre-treatment agent, preferably from 0.05 g/l to 20 g/l.

Preferably, the first pre-treatment agent, more preferably cleaning agent with or without conditioning agent comprises sodium hydroxide from 0 g/l to 30 g/l based on the total volume of the first pre-treatment agent.

Preferably, sub-step (p-1) is performed at a temperature from 40° C. to 70° C., more preferably from 50° C. to 60° C., and most preferably at 60° C.

Preferably, sub-step (p-2) is performed for a duration from 0.5 min to 6 min, preferably from 1 min to 5 min.

Preferably, the second pre-treatment agent, more preferably etching/cleaning agent comprises an acid and an oxidizing agent able to oxidize the surface such as H₂O₂ or sodium persulfate, and most preferably is selected as the commercially available Etch Cleaner NaPS.

Preferably, the second pre-treatment agent, more preferably etching/cleaning agent is applied at a concentration from 100 g/l to 300 g/l based on the total volume of the second pre-treatment agent.

Preferably, the second pre-treatment agent, more preferably etching/cleaning agent comprises from 20 ml/l to 50 ml/l of 60 w/w % sulfuric acid based on the total volume of the second pre-treatment agent.

Preferably, sub-step (p-2) is performed at a temperature from 25° C. to 50° C., more preferably from 25° C. to 30° C., and most preferably at 30° C.

Preferably, sub-step (p-2) is performed for a duration from 0.5 min to 2 min, preferably for 1 min.

Preferably, the activation of the plasma-treated surface of the substrate is performed with palladium species, conductive polymers, or carbon species as activation composition.

Preferably, the activation of the plasma-treated surface is performed by adding a metal activation composition as palladium activation composition or copper activation composition in order to deposit e.g. a palladium layer or copper layer onto the plasma-treated surface of the substrate which can be deposited as metallic palladium or metallic copper as film or colloid or in ionic form with subsequent reduction. The metallic layer can be a pure metallic layer or can contain additional metals as metal alloy.

Preferably, the metal activation composition comprises e.g. at least one source of palladium ions or copper ions. Additionally, the solution may comprise other sources of metal ions, as sources of ruthenium ions, sources of rhodium ions, sources of palladium ions, sources of osmium ions, sources of iridium ions, sources of platinum ions, sources of copper ions, sources of silver ions, sources of nickel ions, sources of cobalt ions, sources of gold ions and mixtures thereof. The palladium ions or copper ions and said additional metal ions are being adsorbed on the plasma-treated surface of said substrate and subsequently reduced or are being adsorbed as reduced metals e.g. colloids or particles, e.g. palladium colloids or copper colloids, wherein the palladium colloids may comprise tin or the copper colloids may comprise palladium.

Preferably, the activation composition is selected as the commercially available Neoganth Activator U or Neoganth Activator 834 or Neoganth MV Activator available by Atotech Deutschland Gmbh & Co. KG.

Preferably, the activation composition may comprise carbon, conductive polymers, or metal ions or metal colloids containing e.g. copper, palladium, palladium-tin, for subsequent electrolytic direct metallization.

One advantage, which is achieved by the method according to the first aspect is that the treatment of the surface of the substrate with a plasma beam to obtain the plasma-treated surface allows for a more effective subsequent activation step (ii), which therefore results in an advantageous metal coating of the substrate.

When the optional electroless deposition of a coating metal on the activated surface of the substrate during step (iii) is performed, the activation is preferably done by metal colloids or metal ions during the activation step (ii).

When the optional electroless deposition of a coating metal on the activated surface of the substrate during step (iii) is not performed the activation is preferably done by a coating with conductive polymers or carbon during the activation step (ii).

Preferably step (ii) may comprise sub-steps (ii-1), (ii-2), (ii-3), and/or (ii-4),
wherein sub-step (ii-1) comprises applying a pre-dip agent to the surface of the substrate, preferably to the plasma-treated surface of the substrate, to obtain a dipped surface of the substrate,
wherein sub-step (ii-2) comprises applying the activation composition, preferably the activation composition comprises metal, metal ions or inorganic activation substance as carbon, to the dipped surface of the substrate, to obtain an activated surface of the substrate,
wherein sub-step (ii-3) is optionally and comprises applying a reducing agent to the activated surface of the substrate if the activated surface comprises metal ions, to obtain a reduced surface of the substrate, and/or
wherein sub-step (ii-4) is optionally and comprises applying an enhancing agent to the activated surface of the substrate after step (ii) if the activated surface comprises metal.

Preferably, the sub-step (ii-1) is the first step, followed by sub-step (ii-2) as the second step, which in turn is followed by sub-step (ii-3) as the third step, or is followed by sub-step (ii-4) as fourth step. Preferably sub-step (ii-4) can be omitted.

Preferably, the pre-dip agent of step (ii-1) comprises an acidic solution, more preferably a hydrochloric acid solution or sulfuric acid solution, optionally with an alkali metal salt, more preferably sodium chloride, or optionally with additional surfactants. Most preferably, is selected as the commercially available PreDip A or PreDip MV by Atotech Deutschland Gmbh & Co. KG. Additionally, the pre-dip agent can comprise an alkaline solution in the activation step (ii) by as base and more preferable usage of inorganic bases such as alkali or earth alkaline hydroxides, metal hydroxides or carbonates, phosphates or borates or optionally with additional surfactants and complexing agents. Most preferably, an alkaline pre-dip is selected as the commercially available PreDip W or PreDip E by Atotech Deutschland Gmbh & Co. KG.

Preferably, sub-step (ii-1) is performed from a temperature of 20° C. to 35° C., preferably at 25° C. or 30° C.

Preferably, sub-step (ii-1) is performed for a duration from 5 sec to 3 min, and more preferably for 20 sec to 1 min.

Preferably, sub-step (ii-2) is performed from a temperature of 20° C. to 55° C., and more preferably at 40° C. to 45° C.

Preferably, sub-step (ii-2) is performed for a duration from 5 sec to 10 min, and more preferably for 40 sec to 4 min.

Preferably, the reducing agent used in sub-step (ii-3) comprises boron based reducing agents, sources of hypophosphite ions, hydrazine, hydrazine derivatives, ascorbic acid, iso-ascorbic acid, sources of formaldehyde, glyoxylic acid, sources of glyoxylic acid, glycolic acid, formic acid, sugars, and/or salts of aforementioned acids. Most preferably, the reducing agent is selected as the available Neoganth WA Reducer.

Preferably, sub-step (ii-3) is performed from a temperature of 20° C. to 50° C., and more preferably at 30° C. to 35° C.

Preferably, sub-step (ii-3) is performed for a duration from 5 sec to 6 min, and more preferably for 40 sec to 4 min.

Preferably, the enhancing agent used in sub-step (ii-4) is selected from glyoxylic acid, hypophosphoric acid, or formaldehyde, and most preferably is a formaldehyde solution. Optionally the effect of the enhancing agent can be improved by adjusting the pH to additionally to alkaline.

Preferably, sub-step (ii-4) is performed at a temperature of 20° C. to 50° C., and preferably at 32° ° C. to 34° C.

Preferably, sub-step (ii-4) is performed for a duration from 5 sec to 6 min, preferably for 30 sec to 1 min.

According to another aspect, the present invention is further directed to a substrate with an activated surface obtained by a method according to the first aspect.

A method for plasma-treating a surface of the substrate is preferred, wherein step (iii) comprises applying a coating composition to the activated surface of the substrate, wherein the coating composition comprises at least one coating metal, which is preferably selected from copper, nickel, or alloys thereof, and more preferably is selected as copper.

Preferably, the coating composition used in step (iii) comprises a solvent, more preferably water, and at least one coating metal to be deposited. The preferred solvent is water. Further liquids, that are miscible with water, as for example alcohols such as C₁-C₄-alcohols (e.g. methanol, ethanol, iso-propanol, n-propanol, butanol and/or its regioisomers) and other polar organic liquids, which are miscible with water, may be added. Preferably, at least 90.0 wt.-%, more preferably 99.0 wt.-% or more, of the coating composition used in step (iii) is water for its ecological benign character.

Further optional components of the coating composition used in step (iii) are complexing agents or chelating agents for said coating metal ion, reducing agents for said coating metal ions, stabilizing agents, co-solvents, wetting agents, and/or functional additives such as brighteners, accelerators, suppressors, anti-tarnish agents. The coating composition used in step (iii) may further comprise sources of nickel ions, sources of cobalt ions and mixtures thereof.

The preferred copper ions may be included in the inventive coating composition used in step (iii) by any (water soluble) copper salt or other (water soluble) copper compound suitable to liberate copper ions in a liquid medium such as an aqueous solution. Preferably, the copper ions are added as copper sulfate, copper chloride, copper nitrate, copper acetate, copper methanesulfonate ((CH₃O₃S)₂Cu), one or more hydrates of any of the aforementioned or mixtures of the aforementioned. The concentration of the copper ions in the inventive coating composition used in step (iii) preferably ranges from 0.1 g/l to 20 g/l, more preferably from 1 g/l to 10 g/L, even more preferably from 2 g/l to 5 g/l.

Preferably, the coating composition used in step (iii) comprises at least one reducing agent suitable for reducing copper ions to metallic copper. Said at least one reducing agent is thus capable of converting copper(I)-ions and/or copper(II)-ions present in the coating composition used in step (iii) to elemental copper. The reducing agent is preferably selected from the group consisting of formaldehyde; paraformaldehyde; glyoxylic acid; sources of glyoxylic acid; aminoboranes such as dimethylaminoborane; alkali borohydrides such as NaBH₄, KBH₄; hydrazine; polysaccharides; sugars such as glucose; hypophosphoric acid; glycolic acid; formic acid; ascorbic acid; salts and mixtures of any of the aforementioned. If the coating composition used in step (iii) contains more than one reducing agent, it is preferable that the further reducing agent is an agent that acts as reducing agent but cannot be used as the sole reducing agent (cf. U.S. Pat. No. 7,220,296, col. 4, I. 20-43 and 54-62). Such further reducing agent is in this sense also called an “enhancer”.

The term “source of glyoxylic acid” encompasses glyoxylic acid and all compounds that can be converted to glyoxylic acid in liquid media such as an aqueous solution. In aqueous solution the aldehyde containing acid is in equilibrium with its hydrate. A suitable source of glyoxylic acid is dihaloacetic acid, such as dichloroacetic acid, which will hydrolyze in a liquid medium such as an aqueous medium to the hydrate of glyoxylic acid. An alternative source of glyoxylic acid is the bisulfite adduct. The bisulfite adduct may be added to the composition or may be formed in situ. The bisulfite adduct may be made from glyoxylate and either bisulfite, sulfite or metabisulfite.

The concentration of the at least one reducing agent in the coating composition used in step (iii) preferably ranges from 0.02 mol/l to 0.3 mol/l, more preferably from 0.054 mol/l to 0.2 mol/l, even more preferably from 0.1 mol/l to 0.2 mol/l. In case more than one reducing agent is comprised in the inventive coating composition used in step (iii), the sum of concentrations of all reducing agents is within the above ranges.

Preferably, the coating composition used in step (iii) comprises at least one complexing agent for copper ions. Such complexing agent is sometimes referred to as chelating agent in the art. The at least one complexing agent is capable of forming a coordination compound with copper(I)-ions and/or copper(II)-ions present in the coating composition used in step (iii). Preferable complexing agents are sugar alcohols such as xylitol, mannitol and sorbitol; alkanol amines such as triethanol amine; hydroxycarboxylic acids such as lactic acid, citric acid and tartaric acid; aminophosphonic acids and aminopolyphosphonic acids such as aminotris(methylphosphonic acid); aminocarboxylic acids such as oligoamino monosuccinic acid, polyamino monosuccinic acid including oligoamino disuccinic acids like ethylenediamine-N,N′-disuccinic acid, polyamino disuccinic acids, aminopolycarboxylic acids such as nitrilotriacetic acid, ethylenediamine tetraacetic acid (EDTA), N′-(2-hydroxyethyl)-ethylene diamine-N,N, N′-triacetic acid (HEDTA), cyclohexanediamine tetraacetic acid, diethylenetriamine pentaacetic acid, and tetrakis-(2-hydroxypropyl)-ethylenediamine and N,N,N′,N′-tetrakis(2-hydroxyethyl) ethylenediamine, salts and mixtures of any of the aforementioned.

More preferably, the at least one complexing agent is selected from the group consisting of xylitol; tartaric acid; ethylenediamine tetraacetic acid (EDTA); N′-(2-hydroxyethyl)-ethylene diamine-N,N,N′-triacetic acid (HEDTA); tetrakis-(2-hydroxypropyl)-ethylenediamine; salts and mixtures of any of the aforementioned.

Preferably, the concentration of the at least one complexing agent in the coating composition used in step (iii) ranges from 0.004 mol/l to 1.5 mol/l, more preferably from 0.02 mol/l to 0.6 mol/l, even more preferably from 0.04 mol/l to 0.4 mol/l. In case more than one complexing agent is used, the concentration of all complexing agents lies preferably in above-defined ranges.

Preferably, the molar ratio of the at least one complexing agent (which means in this connection the total amount of all complexing agent(s)) to copper ions ranges from 1.3:1 to 5:1, more preferably 2:1 to 5:1. This embodiment is particularly advantageous if the coating composition used in step (iii) is agitated during deposition, preferably agitated with a gas such as air, and/or when a further reducing agent (also called “enhancer”) is used in addition to a first reducing agent such as glyoxylic acid or formaldehyde, wherein the further reducing agent is preferably selected from glycolic acid, hypophosphoric acid, or formic acid, most preferably glycolic acid.

Preferably the coating composition used in step (iii) is selected as the commercially available Printoganth P Plus or Printoganth MV TP1.

A method for plasma-treating a surface of the substrate is preferred, wherein step (iii) is performed for a duration from 1 min to 30 mins, preferably 4 mins or 20 to 30 mins, and/or at a temperature from 10° C. to 50° C., preferably at 32° C. to 34° C.

A method for plasma-treating a surface of the substrate is preferred, wherein said method comprises the following step (iv),
(iv) electrolytic deposition of an additional coating metal on the plating surface of the substrate obtained after optional step (iii) or on the activated surface of the substrate obtained after step (ii).

The electrolytic deposition of the additional coating metal allows for an effective deposition of metal coating on the substrate surface in order to obtain an electrolytic metal coated surface.

Depending on the activation composition used during the activation step (ii), for example when carbon or conductive polymer is used as an activation composition, the optional electroless deposition step (iii) can be omitted, so that during the electrolytic deposition step (iv), the additional coating metal can be directly deposited on the activated surface of the substrate obtained after the activation step (ii).

Depending on the activation composition used during the activation step (ii), for example when a palladium species is used as an activation composition, the optional electroless deposition step (iii) has to be performed before the electrolytic deposition step (iv), so that during the electrolytic deposition step (iv) the additional coating metal is deposited on the plating surface of the substrate obtained after the electroless deposition step (iii).

Preferably, the additional coating metal used during the electrolytic deposition step (iv) is selected from copper, nickel or alloys thereof, and more preferably is selected as copper.

Preferably, the electrolytic deposition step (iv) is performed by applying electrolytic copper plating baths, which for this purpose are well known in the art.

Preferably, said electrolytic copper plating baths comprise copper ions, an electrolyte (typically a strong acid such as sulfuric acid, fluoroboric acid or methanesulfonic acid), chloride ions, optionally one or more leveler, optionally one or more brightener and optionally one or more carrier. These compounds are known in the art and are disclosed for example in WO 2017/037040 A1 (page 21, line 1 to page 22, line 27).

Preferably step (iv) is performed for a duration from 30 min to 120 min, preferably for 90 min, and/or at a temperature from 10° C. to 50° C., preferably at 32° C.

Preferably step (iv) is performed by applying a current density from 1 ASD to 25 ASD, preferably by applying a current density from 3 ASD to 15 ASD.

A method for plasma-treating a surface of a substrate is preferred, wherein the substrate, in particular a dielectric substrate having at least one dielectric surface to be treated, comprises organic polymers selected from resins and/or plastics, and blends thereof, wherein resins and plastics are more preferably selected from the group consisting of epoxy resin, isocyanate resin, bismaleimide triazine resin, phenylene resin, polyester, even more preferably selected from polyethylene terephthalate (PET), polyimide (PI), polytetrafluorethylene, acrylonitrile-butadiene-styrene (ABS) copolymer, polyamide (PA), polycarbonate (PC), liquid crystal polymer (LCP) as cyclic olefin copolymer (COC), Ajinomoto build-up films (ABF, ABF/epoxy-type substrate), or plastics made for photo-imagable dielectrics as well as mixtures and blends of the aforementioned, or a composite basing on a mixture of glass fillers and/or silica fillers and/or glass fabrics with said organic polymers. The substrate can also be a glass substrate or a silicon substrate.

Therefore, the plasma-treatment step (i) can be applied to a wide variety of substrates.

The dielectric substrate as resins and plastics preferably comprise materials typically used in the electronics industry which are to be metallized.

Preferably, the organic polymers comprise polyimide resins or epoxy resins, wherein the polyimide resins can be modified by the addition of polysiloxane, polycarbonate, polyester, or the like.

Preferably, the epoxy resins can be a glass filler epoxy board material comprising a combination of the epoxy resin and glass filler, or the same modified to have a low thermal expansion and a high glass-transition temperature, constituting a high glass-transition temperature glass filler epoxy board material.

Preferably, the glass filler is selected from borosilicate glass, quartz glass, silica glass, and/or fluorinated glass. Silicon preferably includes polysilicon (including doped polysilicon such as p-doped polysilicon and n-doped polysilicon) and monocrystalline silicon, silicon oxide, silicon nitride as well as silicon oxynitride. The size of different filler has a range from 0.01 μm to 5 μm in diameter with preferably an average of 0.5 μm in diameter.

The glass fabrics are selected similar to glass fillers from borosilicate glass, quartz glass, silica glass and/or fluorinated glass. They are woven from individual glass fibers with diameters ranging from submicrometers to several micrometers in diameter. They give the printed circuit board mechanical stability and, together with the resins used, significantly influence the mechanical and thermal properties of the printed circuit board material.

Preferable the composite of the nonconductive layer is a build-up film, e.g. epoxy base materials. The size of the embedded glass filler has an average of 0.5 μm in diameter, with a maximum of 5.0 μm.

A method for plasma-treating a surface of the substrate is preferred, the surface of the substrate is an external surface of the substrate comprises a hole surface, delimiting the through-holes (THs) and blind micro vias (BMVs), wherein steps (i), (ii), optionally (iii) and optionally (iv) are performed on said surface.

This allows for an effective plasma-treatment of the respective hole surface.

A method for plasma-treating a surface of the substrate is preferred, wherein the plasma beam during step (i) is directed to the surface of the substrate.

This allows for a precise direction of the plasma beam to the surface of the substrate, such that a specific region of the substrate surface can be treated, which is in particular in contrast to conventionally used diffuse plasma cloud, which is not directed to a specific region of the substrate surface, but to the overall substrate instead.

Preferably, the plasma beam during step (i) is focused to the surface of the substrate.

A method for plasma-treating a surface of the substrate is preferred, wherein the plasma beam during step (i) is formed by air plasma, forming gas plasma, oxygen gas plasma, or inert gas plasma as nitrogen or argon plasma. In a preferred embodiment the plasma beam during step (i) is formed by forming gas plasma.

This allows for an optimal adaption of the plasma beam according to the required properties of the substrate.

If for example air plasma or oxygen gas plasma is used for the plasma beam during step (i), the surface of the substrate is oxidized.

Preferably, forming gas comprises inert gas, preferably nitrogen gas, and hydrogen gas, wherein the inert gas is more preferably present at a concentration from 90 vol % to 99 vol %, even more preferably from 90 vol % to 95 vol % based on the total volume of the forming gas.

If for example forming gas plasma is used for the plasma beam during step (i), the surface of the substrate is reduced.

A method for plasma-treating a surface of the substrate is preferred, wherein the plasma beam during step (i) is generated by a plasma generator, comprising a nozzle through which the generated plasma exits the plasma source.

The nozzle of the plasma generator allows for a precise direction of the plasma beam towards the surface of the substrate during step (i).

A method for plasma-treating a surface of the substrate is preferred, wherein the distance between the nozzle and the surface of the substrate is maintained constant during step (i), preferably from 5 mm to 25 mm, and/or wherein during step (i) the nozzle is moved in respect to the substrate with a constant velocity, preferably from 50 mm/second to 250 mm/second.

By applying a constant distance between the nozzle and the surface of the substrate it can be ensured that a uniform plasma-treatment of the surface of the substrate is ensured, without exposing certain regions of the surface to higher energy doses.

Depending on the specific distance of the nozzle and the surface, the properties of the plasma directed to the surface can be changed. For example, if the distance between the nozzle and the surface is below 10 mm, the interaction of ionic components of the plasma beam with substrate surface are higher in relation to the radical components, which results in a higher energy dose per area, which results in an increase of activated surface groups on the substrate surface. For example, if the distance between the nozzle and the surface is above 10 mm, the interaction of the ionic components with the substrate surface is reduced in relation to radical components of the plasma beam, which results in an increased adhesive strength of the subsequently adhered activation layer depending on material type.

By applying a constant velocity, the nozzle can be moved above the surface of the substrate, which allows for uniform plasma treatment of the entire substrate surface.

A method for plasma-treating a surface of the substrate is preferred, wherein the plasma beam generated during step (i) comprises a discharge power per nozzle from 250 W to 700 W, preferably 400 W.

The specific discharge power of the plasma beam generated during step (i) can be adapted to the specific activation profiles according to the respective substrate used.

A method for plasma-treating a surface of the substrate is preferred, wherein step (i) is performed from one cycle to five cycles, preferably from one cycles to three cycles.

By repeating the step (i) for subsequent cycles, the regions of the substrate to be plasma-treated are brought in contact with the plasma beam for multiple times, which allows for a particularly effective plasma-treated surfaces, which in allows for an increase in the adhesive strength of the metal coating to be adhered subsequently.

A method for plasma-treating a surface of the substrate is preferred, wherein during step (i) the temperature of the surface of the substrate exposed to the plasma beam is maintained below a temperature threshold, which preferably is lower than the specific glass transition temperature Tg of the substrate.

Therefore, by selecting the temperature below the specific glass transition temperature Tg of the substrate, damaging the substrate can be prevented.

A method for plasma-treating a surface of the substrate is preferred, wherein method steps (i), (ii), (iii) and/or (iv) are performed in a horizontal process or in a vertical process.

This allows for an effective adaptation of the method according to the first aspect to several manufacturing scenarios, thereby increasing the flexibility of said method.

According to the present invention, a horizontal or vertical process refers to the orientation of the substrate during the respective method steps (i), (ii), (iii) and/or (iv).

During a horizontal process, the substrate, which in particular is formed as plate, is transferred through method steps (i), (ii), (iii) and/or (iv) in a horizontal orientation, so that the lower side of the substrate faces towards the floor and the upper side of the substrate faces away from the floor. During the horizontal process, the substrate is preferably conveyed by a transport device to be processed in different treatment modules during the respective method steps (i), (ii), (iii), and/or (iv).

During a vertical process, the substrate, which in particular is formed as plate, is transferred through method steps (i), (ii), (iii) and/or (iv) in a vertical orientation, so that one lateral edge of the substrate faces towards the floor and the opposite lateral edge of the substrate faces away from the floor.

According to a second aspect the present invention is further directed to a substrate with a metal coated surface obtained by a method according to the first aspect.

Preferably, the aforementioned regarding the method according to the first aspect of the present invention, preferably what is described as being preferred, applies likewise to the substrate of the second aspect of the present invention.

### EXAMPLES

In the following varying examples are provided to specify methods for plasma-treating a surface of a substrate.

Typically, the methods specified in the following examples start with an desmear process (t), comprising sub-steps (t-1), (t-2) and (t-3), which is followed by the plasma-treating step (i), which in turn is followed by the optional pre-treatment process (p), comprising sub-steps (p-1) and/or (p-2).

After the optional pre-treatment process (p), an activation step (ii), comprising sub-steps (ii-1), (ii-2) and (ii-3), is performed, which in turn is followed by an electroless coating metal deposition step (iii), to obtain a plating surface of the substrate.

After the electroless deposition step (iii) an optional annealing step, a subsequent electrolytic coating metal deposition step (iv), and an additional subsequent annealing step are performed to obtain the metal coated substrate.

In order to provide better comparison of effects, the varying examples summarized in the following comprise certain examples comprising a plasma treating step (i) using forming gas, a desmear process (t) and a pre-treatment process (p), while certain examples do not comprise said plasma treating step (i), desmear process (t) and/or a pre-treatment process (p) or do not comprise certain sub-steps thereof.

The resulting metal coated surfaces of the respective substrates according to the examples are analyzed in respect to their adhesive properties, in particular by a peel strength test to determine the force required to peel out the coating from the substrate, wherein said peeling force is measured in N/cm. The peel strength test is performed according to IPC-TM-650 electronic standard.

### Example 1

According to example 1, the difference in adhesive properties of the coating is shown, either without a plasma-treatment step (see Exp. 1—Comparative Example) or with a plasma treatment step (see Exp. 2—Inventive Example).

The plating process according to example 1 comprises a horizontal plating process.

In both Experiments 1 and 2 an epoxy-type polymer substrate (substrate MEG6 obtained from Panasonic) was subjected to a desmear process (t), wherein in the first sub-step (t-1) Securiganth MV Sweller was applied for 5 min at 70° C., wherein in the second sub-step (t-2) Securiganth P500 was applied for 10 min at 80° C., and wherein in the third sub-step (t-3) MV Reduction Conditioner was applied for 5 min at 50° C.

Afterwards, for Experiment 2 only, a plasma-treatment step (i) is performed for three cycles at 400 W with a nozzle-substrate distance of 7 mm and a relative velocity of 50 mm/s.

Afterwards, for both Experiments 1 and 2, a pre-treatment step (p) is performed, wherein in the first sub-step (p-1) Securiganth Cleaner V8 was applied for 1 min at 60° C., and wherein in the second sub-step (p-2) Etch Cleaner NaPS was applied for 1 min at 30° C.

Afterwards, for both Experiments 1 and 2, an activation step (ii) is performed, which comprises a first sub-step (ii-1), wherein the solution PreDip B was applied for 20 sec at 25° C., a second sub-step (ii-2), wherein the Neoganth Activator U was applied for 40 sec at 45° C., and a third sub-step (ii-3), wherein the Neoganth WA Reducer was applied for 40 sec at 35° C.

After the activation step (ii), for both Experiments 1 and 2, an electroless copper deposition step (iii) was performed by applying the Printoganth P Plus solution for 6 min at 32° C., followed by an annealing process for 30 min at 120° C., followed by an electrolytic copper deposition step for 90 min at 3.2 A, and followed by a further annealing process performed for 60 min at 180° C.

Afterwards the adhesion properties of the obtained coating layer is analyzed in a peel-strength test, wherein the respective results are summarized in Table 1.

TABLE 1
Coating properties of epoxy-type substrate

| | | Adhesion |
|---|---|---|
| Exp. | Plasma-treatment | (N/cm) |
| E1 | None | 2.0 |
| E2 | 3 cycles at 400 W, nozzle-substrate | 3.5 |
| | distance of 7 mm, relative velocity of | |
| | 50 mm/s. | |

As can be derived from table 1, the plasma-treatment step according to experiment 2 (Inventive Example) results in an increased adhesion of the coating layer, compared to a method wherein the plasma-treatment step has been omitted according to experiment 1 (Comparative Example).

### Example 2

According to example 2, the difference in adhesive properties of the coating is shown, either without a plasma-treatment step (see Exp. 3, 4—Comparative Example) or with a plasma treatment step (see Exp. 5, 6—Inventive Example).

The plating process according to example 2 is similar to example 1 except that a vertical plating process was employed, and except for the following differences:
During sub-step (t-1) the Securiganth MV Sweller was applied for 10 min at 60° ° C. and during sub-step (t-2) Securiganth P500 was applied for 20 min at 80° ° C.
For experiments 4 and 6 during sub-step (t-3) instead of the MV Reduction Conditioner a reduction solution, comprising hydrochloric acid, citric acid and hydrogen peroxide, was applied for 5 min at 50° C.
During sub-step (p-1) Cleaner 902 was applied for 5 min at 60° C.
During sub-step (ii-1) the solution PreDip MV was applied for 1 min at 25° C., during sub-step (ii-2) the Neoganth Activator 834 was applied for 4 min at 40° ° C., and during sub-step (ii-3), the Neoganth WA Reducer was applied for 3 min at 35° C.
During the electroless copper deposition step (iii) the Printoganth MV TP1 was applied for 20 min at 34° C.

Afterwards the adhesion properties of the obtained coating layer is analyzed in a peel-off test, wherein the respective results are summarized in Table 2.

TABLE 2
Coating properties of epoxy-type substrate

| | | Adhesion |
|---|---|---|
| Exp. | Plasma-treatment | (N/cm) |
| E3 | None | 2.0 |
| E4 | None | 3.5 |
| E5 | 3 cycles at 400 W, nozzle-substrate | 6.0 |
| | distance of 7 mm, relative velocity of | |
| | 50 mm/s | |
| E6 | 3 cycles at 400 W, nozzle-substrate | 6.0 |
| | distance of 7 mm, relative velocity of | |
| | 50 mm/s | |

As can be derived from table 2, the plasma-treatment step according to experiment 5 and 6 (Inventive Example) results in an increased adhesion of the coating layer, compared to a method wherein the plasma-treatment step has been omitted according to experiments 3 and 4 (Comparative Example).

### Example 3

According to example 3, the difference in adhesive properties of the coating is shown, either without a plasma-treatment step (see Exp. 7, 8—Comparative Example) or with a plasma treatment step (see Exp. 9, 10—Inventive Example).

The horizontal plating process according to example 3 is similar to example 1 except that a ABF/epoxy-type substrate (substrate GY16B obtained from Ajinomoto) was used and except for the following differences:
For experiments 8 and 10 during sub-step (t-3) a Reduction solution was applied for 5 min at 50° C.

Afterwards the adhesion properties of the obtained coating layer is analyzed in a peel-off test, wherein the respective results are summarized in Table 3.

TABLE 3
Coating properties of ABF/epoxy-type substrate

| | | Adhesion |
|---|---|---|
| Exp. | Plasma-treatment | (N/cm) |
| E7 | None | 2.0 |
| E8 | None | 4.5 |
| E9 | 3 cycles at 400 W, nozzle-substrate | 6.0 |
| | distance of 7 mm, relative velocity of | |
| | 50 mm/s | |
| E10 | 3 cycles at 400 W, nozzle-substrate | 6.0 |
| | distance of 7 mm, relative velocity of | |
| | 50 mm/s | |

As can be derived from table 3, the plasma-treatment step according to experiment 9 and 10 (Inventive Example) also for the ABF/epoxy-type substrate in the horizontal plating process results in an increased adhesion of the coating layer, compared to a method wherein the plasma-treatment step has been omitted according to experiments 7 and 8 (Comparative Example).

Similar results apply to horizontal plating processes with other ABF/epoxy-type substrates or epoxy-type substrates (data not shown for substrates GL102 and GXT31 obtained from Ajinomoto).

### Example 4

According to example 4, the difference in adhesive properties of the coating is shown, either without a plasma-treatment step (see Exp. 11, 12—Comparative Example) or with a plasma treatment step (see Exp. 13, 14—Inventive Example).

The vertical plating process according to example 4 is similar to example 2 except that a ABF/epoxy-type substrate (substrate GY16B obtained from Ajinomoto) was used.

Afterwards the adhesion properties of the obtained coating layer is analyzed in a peel-off test, wherein the respective results are summarized in Table 4.

TABLE 4
Coating properties of ABF/epoxy-type substrate

| | | Adhesion |
|---|---|---|
| Exp. | Plasma-treatment | (N/cm) |
| E11 | None | 2.5 |
| E12 | None | 4.0 |
| E13 | 3 cycles at 400 W, nozzle-substrate | 5.0 |
| | distance of 7 mm, relative velocity of | |
| | 50 mm/s | |
| E14 | 3 cycles at 400 W, nozzle-substrate | 5.5 |
| | distance of 7 mm, relative velocity of | |
| | 50 mm/s | |

As can be derived from table 4, the plasma-treatment step according to experiment 13 and 14 (Inventive Example) also for the ABF/epoxy-type substrate in the vertical plating process results in an increased adhesion of the coating layer, compared to a method wherein the plasma-treatment step has been omitted according to experiments 11 and 12 (Comparative Example).

Similar results apply to vertical plating processes with other ABF/epoxy-type substrates or epoxy-type substrates (data not shown for substrates GL102 and GXT31 obtained from Ajinomoto).

### Example 5

According to example 5, the difference in adhesive properties of the coating is shown, either without a plasma-treatment step (see Exp. 15—Comparative Example) or with a plasma treatment step (see Exp. 16 and 17).

The horizontal plating process according to example 5 is similar to example 1 except for the following differences:
For experiments 15, 16 and 17, the epoxy-type substrate HS100 from Hitachi was used.
For experiment 16 (Comparative Example) no desmear process (t) and no pre-treatment process (p) was employed at all
For experiments 16 and 17, the plasma-treatment was performed for one cycle at 400 W with a nozzle-substrate distance of 10 mm, and a relative velocity of 100 mm/s

Afterwards the adhesion properties of the obtained coating layer is analyzed in a peel-off test, wherein the respective results are summarized in Table 5.

TABLE 5
Coating properties of epoxy-type substrate

| | | Adhesion |
|---|---|---|
| Exp. | Plasma-treatment | (N/cm) |
| E15 | None | 3.0 |
| E16 | 1 cycle at 400 W, nozzle-substrate | 3.0 |
| | distance of 10 mm, relative velocity | |
| | of 100 mm/s | |
| E17 | 1 cycle at 400 W, nozzle-substrate | 9.0 |
| | distance of 10 mm, relative velocity | |
| | of 100 mm/s | |

When comparing experiment 17 (Inventive Example) with experiment 16 (Comparative Example) a significant increase in adhesion power can be observed when the desmear process (t) and the pre-treating process (p) are omitted.

### Example 6

According to example 6, the difference in adhesive properties of the coating is shown, either without a plasma-treatment step (see Exp. 18, 20—Comparative Example) or with a plasma treatment step (see Exp. 19, 21—Inventive Example).

The vertical plating process according to example 6 is similar to example 2 except that an liquid crystal polymer substrate was used (substrate CTQ-100 obtained from Kuraray) and except for the following differences:
In all Experiments 18, 19, 20 and 21 in sub-step (t-3) a Reduction solution was used for 5 min at 50° C.
In Experiments 18 and 19 Securiganth Cleaner V8 was used during sub-step (p-1) for 1 min at 60° C.
In Experiments 20 and 21 Cleaner 902 was used during sub-step (p-1) for 5 min at 60° C.

Afterwards the adhesion properties of the obtained coating layer is analyzed in a peel-off test, wherein the respective results are summarized in Table 6.

TABLE 6
Coating properties of liquid crystal polymer-type substrate

| | | Adhesion |
|---|---|---|
| Exp. | Plasma-treatment | (N/cm) |
| E18 | None | 4.5 |
| E19 | 3 cycles at 400 W, nozzle-substrate | 8.5 |
| | distance of 7 mm, relative velocity | |
| | of 50 mm/s | |
| E20 | None | 4.0 |
| E21 | 3 cycles at 400 W, nozzle-substrate | 6.5 |
| | distance of 7 mm, relative velocity of | |
| | 50 mm/s | |

When comparing experiments 21 and 19 (Inventive Example) with experiments 20 and 18 (Comparative Example), respectively, a significant increase in adhesion power can be observed when plasma-treatment is performed, also when using different agents in pre-treatment step (p-1) compared to example 2.

1. A method for plasma-treating a surface of a dielectric substrate comprising through holes (THs) and/or blind micro vias (BMVs), the method comprising the following steps:
(t) wet-chemical treating the surface of the substrate with treatment solutions of a desmear process to remove residues from the surface of the substrate in order to obtain a wet-chemical treated surface of the substrate,
(i) treating the wet-chemical treated surface of the substrate with a plasma beam under atmospheric pressure, to obtain a plasma-treated surface of the substrate,
(ii) activation of the plasma-treated surface of the substrate with an activation composition, to obtain an activated surface of the substrate,
(iii) optionally electroless deposition of a coating metal on the activated surface of the substrate, to obtain a plating surface of the substrate, and
(iv) optionally electrolytic deposition of an additional coating metal on the plating surface of the substrate obtained after optional step (iii) or on the activated surface of the substrate obtained after step (ii) in order to obtain an electrolytic metal coated surface.

2. The method according to claim 1, wherein step (t) comprises applying sub-steps for swelling, etching and reducing treatment and optionally rinsing and/or cleaning treatment of the surface of the substrate.

3. The method according to claim 1, wherein step (t) comprises sub-steps (t-1), (t-2) and (t-3),
wherein sub-step (t-1) comprises applying a first treatment agent, preferably a swelling agent, to the surface of the substrate, to obtain a swollen surface of the substrate,
wherein sub-step (t-2) comprises applying a second treatment agent, preferably an etching agent, to the surface of the substrate, to obtain an etched surface of the substrate, and
wherein sub-step (t-3) comprises applying a third treatment agent to the surface of the substrate.

4. The method according to claim 1 wherein no curable polymer layer is deposited onto the wet-chemical treated surface and/or the plasma-treated surface.

5. The method according to claim 1, further comprising the following step (p), which is performed before or after step (i),
(p) pre-treating a surface of the substrate with a pre-treatment process to obtain a pre-treated surface of the substrate.

6. The method according to claim 5, wherein step (p) further comprises sub-steps (p-1), and/or (p-2),
wherein sub-step (p-1) comprises applying a first pre-treatment agent, to the surface of the substrate, to obtain a cleaned and conditioned surface of the substrate, and/or
wherein sub-step (p-2) comprises applying a second pre-treatment agent, to the surface of the substrate.

7. The method according to claim 1, wherein step (iii) comprises applying a coating composition to the activated surface of the substrate, wherein the coating composition comprises the coating metal.

8. The method according to claim 1 wherein step (iii) is performed for a duration from 1 min to 30 mins, and/or at a temperature from 10° C. to 50° C.

9. The method according to claim 1, wherein the substrate comprises organic polymers or a composite basing on a mixture of glass fillers and/or silica fillers and/or glass fabrics with said organic polymers.

10. The method according to claim 1, wherein the surface of the substrate is an external surface of the substrate comprises a hole surface, delimiting the through-holes (THs) and blind micro vias (BMVs), wherein steps (i), (ii), optionally (iii) and optionally (iv) are performed on said surface.

11. The method according to claim 1, wherein the plasma beam during step (i) is formed by air plasma, forming gas plasma, oxygen gas plasma or inert gas plasma.

12. The method according to claim 1, wherein the plasma beam during step (i) is generated by a plasma generator, comprising a nozzle through which the generated plasma exits the plasma source.

13. The method according to claim 12, wherein the distance between the nozzle and the surface of the substrate is maintained constant during step (i), and/or wherein during step (i) the nozzle is moved in respect to the substrate with a constant velocity.

14. The method according to claim 12, wherein the plasma beam generated during step (i) comprises a discharge power per nozzle from 250 W to 700 W.

15. The method according to claim 1, wherein during step (i) the temperature of the surface of the substrate exposed to the plasma beam is maintained below a temperature threshold.

16. The method according to claim 2, wherein sub-step (t-2) is performed for a duration from 1 min to 20 min.

17. The method according to claim 1, wherein the peel strength adhesion of the obtained substrate surface after performing the inventive method steps (t) to (iv) is at least 25% improved over performing step (t) or step (i) alone.

18. The method according to claim 1, wherein the peel strength adhesion of the obtained substrate surface after performing the inventive method steps (t) to (iv) is 5 N/cm or higher.

19. Substrate with a metal coated surface obtained by a method according to claim 1.
